(19) United States
(12) Patent Application Publication
(10) Pub. No.: US 2025/0126898 A1
(43) Pub. Date: Apr. 17, 2025

(54) SEMICONDUCTOR DEVICE

(71) Applicant: FUJI ELECTRIC CO., LTD., Kawasaki-shi (JP)

(72) Inventor: Kaname MITSUZUKA, Matsumoto-city (JP)

(73) Assignee: FUJI ELECTRIC CO., LTD., Kawasaki-shi (JP)

(21) Appl. No.: 18/818,299

(22) Filed: Aug. 28, 2024

(30) Foreign Application Priority Data
Oct. 13, 2023 (JP) 2023-177426

(51) Int. Cl. H01L 27/02; H01L 29/739

(52) U.S. Cl. CPC H10D 89/60; H10D 12/481

(57) ABSTRACT

On a single semiconductor substrate, a main semiconductor device is provided in an active-region operating region and a current sensing portion for detecting overcurrent flowing through the main semiconductor device is provided in a sensing region. The main semiconductor device and the current sensing portion are vertical IGBTs with a trench gate structure. All cells of the main semiconductor device have a CS region. Some of the cells of the current sensing portion have the same structure as the structure of the cells of the main semiconductor device while some of the cells have a structure that is free of CS regions but otherwise the same as the structure of the cells of the main semiconductor device. An average carrier concentration of the CS regions per unit area of the sensing region is less than that of the CS regions per unit area of the active-region operating region.

### CROSS REFERENCE TO RELATED APPLICATIONS

This application is based upon and claims the benefit of priority of the prior Japanese Patent Application No. 2023-177426, filed on Oct. 13, 2023, the entire contents of which are incorporated herein by reference.

### BACKGROUND OF THE INVENTION

### 1. Field of the Invention

Embodiments of the disclosure relate to a semiconductor device.

### 2. Description of the Related Art

International Publication No. WO 2020/208738 discloses a configuration in which a sensing IGBT portion is incorporated as a current detecting device for detecting overcurrent flowing through a main insulated-gate bipolar transistor (IGBT) portion, thereby reducing holes injected into a drift region in the sensing IGBT portion, whereby the conductivity modulation effect is relatively lower in the sensing IGBT portion than in the main IGBT portion. Japanese Patent No. 5340961 recites a similar technique.

### SUMMARY OF THE INVENTION

According to an embodiment of the present disclosure, a semiconductor device includes: a semiconductor substrate having a first main surface and a second main surface opposite to each other; a first device region of the semiconductor substrate; a second device region of the semiconductor substrate outside the first device region; a first device provided in the first device region; a second device provided in the second device region; a first semiconductor region of a first conductivity type, provided in the semiconductor substrate, the first semiconductor region being common to the first device and the second device; a second semiconductor region of a second conductivity type, provided between the second main surface of the semiconductor substrate and the first semiconductor region, the second semiconductor region being common to the first device and the second device; and a back electrode provided at the second main surface of the semiconductor substrate and electrically connected to the second semiconductor region. The first device includes: a third semiconductor region of the second conductivity type, provided in the first device region, between the first main surface of the semiconductor substrate and the first semiconductor region; a plurality of fourth semiconductor regions of the first conductivity type, selectively provided between the first main surface of the semiconductor substrate and the third semiconductor region; a first storage region of the first conductivity type, provided between the third semiconductor region and the first semiconductor region, the first storage region having a doping concentration higher than a doping concentration of the first semiconductor region; a plurality of first trenches penetrating through the plurality of fourth semiconductor regions and the third semiconductor region from the first main surface of the semiconductor substrate and terminating in the first semiconductor region; a plurality of first gate insulating films provided in the plurality of trenches, respectively; a plurality of first gate electrodes provided in the plurality of first trenches, on the plurality of first gate insulating films, respectively; and a first electrode provided at the first main surface of the semiconductor substrate and electrically connected to the third semiconductor region and the plurality of fourth semiconductor regions. The second device includes: a fifth semiconductor region of the second conductivity type, provided in the second device region, between the first main surface of the semiconductor substrate and the first semiconductor region; a plurality of sixth semiconductor regions of the first conductivity type, selectively provided between the first main surface of the semiconductor substrate and the fifth semiconductor region; a second storage region of the first conductivity type, provided between the fifth semiconductor region and the first semiconductor region, the second storage region having a doping concentration higher than the doping concentration of the first semiconductor region; a plurality of second trenches penetrating through the plurality of sixth semiconductor regions and the fifth semiconductor region from the first main surface of the semiconductor substrate and terminating in the first semiconductor region; a plurality of second gate insulating films provided in the plurality of second trenches, respectively; a plurality of second gate electrodes provided in the plurality of second trenches, on the second gate insulating films, respectively; and a second electrode provided at the first main surface of the semiconductor substrate and electrically connected to the fifth semiconductor region and the plurality of sixth semiconductor regions. An average carrier concentration of the second storage region per unit area of the second device region is lower than an average carrier concentration of the first storage region per unit area of the first device region.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view depicting a layout when a semiconductor device according to a first embodiment is viewed from a front side of a semiconductor substrate thereof.

FIG. 2 is a plan view depicting an example of another layout when the semiconductor device according to the first embodiment is viewed from the front side of the semiconductor substrate thereof.

FIG. 3 is a cross-sectional view depicting an overview of the structure along cutting line A1-A2 in FIG. 1.

FIG. 4 is a circuit diagram depicting an equivalent circuit of FIG. 3.

FIG. 5 is a cross-sectional view depicting, in detail, the structure along cutting line A1-A2-A3 in FIG. 1.

FIG. 6 is a cross-sectional view depicting an example of a layout of CS regions of a current sensing portion.

FIG. 7 is a cross-sectional view depicting a structure of a semiconductor device according to a second embodiment.

FIG. 8 is a cross-sectional view depicting a state of the semiconductor device according to the second embodiment during manufacture.

FIG. 9 is a cross-sectional view depicting another example of the state of the semiconductor device according to the second embodiment during manufacture.

FIG. 10 is a cross-sectional view depicting a structure of a semiconductor device of a reference example.

### DETAILED DESCRIPTION OF THE INVENTION

First, problems associated with the conventional techniques are discussed. In International Publication No. WO 2020/208738, a phenomenon occurs in which during a Miller period at the time of switching of the IGBT, a sensing voltage that occurs at a sensing resistor due to a sensing current passing through the current detecting device rises rapidly. Due to this phenomenon, a semiconductor circuit device having the IGBT in which the current detecting device is incorporated and an inductive load such as inductance may malfunction.

An overview of an embodiment of the present disclosure is described. (1) A semiconductor device according to one embodiment of the present disclosure is as follows. A first device region and a second device region outside the first device region are provided on a semiconductor substrate. A first device is provided in the first device region. A second device is provided in the second device region. A first semiconductor region of a first conductivity type is provided in the semiconductor substrate and is common to the first device and the second device. Between a back surface of the semiconductor substrate and the first semiconductor region, a second semiconductor region common to the first device and the second device is provided. A back electrode is provided on the back surface of the semiconductor substrate and is electrically connected to the second semiconductor region. The first device includes a third semiconductor region of a second conductivity type, a plurality of fourth semiconductor regions of the first conductivity type, a first storage region of the first conductivity type, a plurality of first trenches, a plurality of first gate electrodes, and a first electrode.

The third semiconductor region is provided in the first device region, between the first main surface of the semiconductor substrate and the first semiconductor region. The plurality of fourth semiconductor regions is selectively provided between the first main surface of the semiconductor substrate and the third semiconductor region. The first storage region is provided between the third semiconductor region and the first semiconductor region. The first storage region has a doping concentration higher than a doping concentration of the first semiconductor region. The plurality of first trenches penetrates through the plurality of fourth semiconductor regions and the third semiconductor region from the first main surface of the semiconductor substrate and terminates in the first semiconductor region. The plurality of first gate electrodes is provided in the plurality of first trenches, via a plurality of first gate insulating films, respectively. The first electrode is provided on the first main surface of the semiconductor substrate and is electrically connected to the third semiconductor region and the plurality of fourth semiconductor regions. The second device includes a fifth semiconductor region of the second conductivity type, a plurality of sixth semiconductor regions of the first conductivity type, a second storage region of the first conductivity type, a plurality of second trenches, a plurality of second gate electrodes, and a second electrode.

The fifth semiconductor region is provided in the second device region, between the first main surface of the semiconductor substrate and the first semiconductor region. The plurality of sixth semiconductor regions are selectively provided between the first main surface of the semiconductor substrate and the fifth semiconductor region. The second storage region is provided between the fifth semiconductor region and the first semiconductor region. The second storage region has a doping concentration higher than the doping concentration of the first semiconductor region. The plurality of second trenches penetrates through the plurality of sixth semiconductor regions and fifth semiconductor region from the first main surface of the semiconductor substrate and terminates first semiconductor region. The plurality of second gate electrodes is provided in the plurality of second trenches, via a plurality of second gate insulating films, respectively. The second electrode is provided on the first main surface of the semiconductor substrate and is electrically connected to the fifth semiconductor region and the plurality of sixth semiconductor regions. An average carrier concentration of the second storage region per unit area of the second device region is lower than an average carrier concentration of the first storage region per unit area of the first device region.

According the disclosure above, in an instance in which the second device is used as a current sensing portion for detecting overcurrent flowing through the first device, when the first and second devices turn on, a rise of a sensing current flowing through the second device may be delayed as compared to the first device. Thus, erroneous operation of a protective function of the first device during normal turn on may be suppressed. Further, a dead time during which a protective operation of the first device is non-responsive may be eliminated or shortened and thus, saturation characteristics of the first device may be improved.

(2) Further, in the semiconductor device according to the disclosure, in (1) described above, the average carrier concentration of the second storage region per unit area of the second device region is 0.2 times to 0.6 times the average carrier concentration of the first storage region per unit area of the first device region.

According to the disclosure above, when the first and second devices turn on, a rise in the sensing voltage is suppressed to a certain extend and tolerance against destruction with respect to dV/dt of the second device is enhanced.

(3) Further, in the semiconductor device according to the disclosure, in (1) or (2) described above, the second storage region may have a plurality of first portions and a plurality of second portions having a carrier concentration lower than a carrier concentration of the plurality of first portions.

According to the disclosure above, imbalance of electric field and the breakdown voltage between cells of the second device may be suppressed.

(4) Further, in the semiconductor device according to the disclosure, in (3) described above, a thickness of each of the plurality of second portions may be thinner than a thickness of each of the plurality of first portions.

According to the disclosure above, the first and second portions of the second storage region may be formed concurrently by a single session of an ion implantation process, whereby manufacturing processes may be simplified.

(5) Further, in the semiconductor device according to the disclosure, in (4) described above, the second storage region has a surface facing the back electrode, the surface being recessed toward the second electrode, at the plurality of second portions thereby forming a wavy shape.

According to the disclosure above, the first and second portions of the second storage region may be formed concurrently by a single session of an ion implantation process, whereby manufacturing processes may be simplified.

(6) Further, in the semiconductor device according to the disclosure, in any one of (3) to (5) described above, the carrier concentration of the plurality of first portions may be a same as a carrier concentration of the first storage region.

According to the disclosure above, the first storage region and the first and second portions of the second storage region may be formed concurrently by a single session of an ion implantation process, whereby manufacturing processes may be simplified.

(7) Further, in the semiconductor device according to the disclosure, in (1) or (2) described above, the carrier concentration of the second storage region may be lower than the carrier concentration of the first storage region over an entire area of the second storage region.

According to the disclosure above, imbalance of breakdown voltage at the surface of second device region may be suppressed.

(8) Further, in the semiconductor device according to the disclosure, in (1) or (2) described above, the first device has a plurality of first cells all having the third semiconductor region, the plurality of fourth semiconductor regions, the first storage region, and the plurality of first gate electrodes. The second device has a plurality of second cells fewer in number than a number of first cells of the plurality of first cells of the first device. The plurality of second cells may include a plurality of third cells having the fifth semiconductor region, the plurality of sixth semiconductor regions, the second storage region, and the plurality of second gate electrodes, and a plurality of fourth cells having the fifth semiconductor region, the plurality of sixth semiconductor regions, and the plurality of second gate electrodes, the plurality of fourth cells being free of the second storage region.

According to the disclosure above, the plurality of third cells of the second device may have a same structure as the structure of the plurality of first cells of the first device. Due to the plurality of fourth cells of the second device, the second storage region is disposed less densely in the second device region and the average carrier concentration of the second storage region per unit area of the second device region may be lower than the average carrier concentration of the first storage region per unit area of the first device region.

(9) Further, in the semiconductor device according to the disclosure, in (8) described above, the plurality of third cells and the plurality of fourth cells may be disposed repeatedly at a constant period.

According to the disclosure above, imbalance of breakdown voltage at the surface of the second device region may be suppressed.

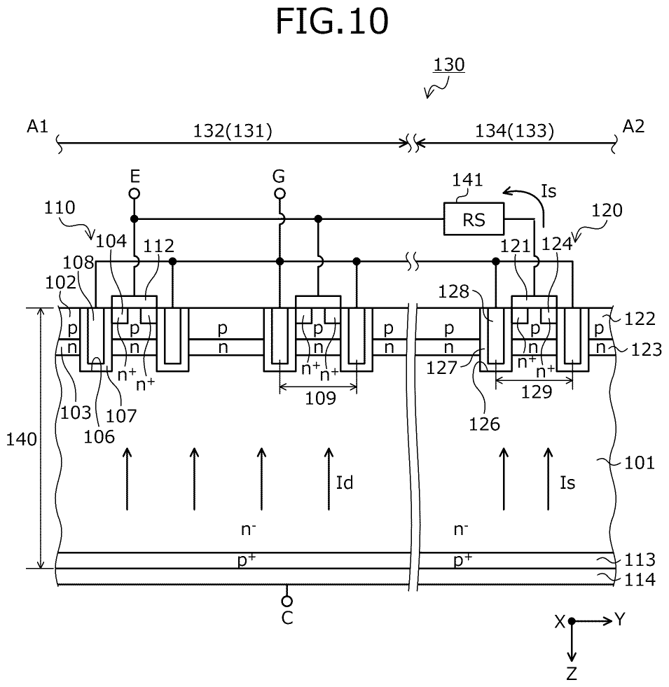

Findings underlying the present disclosure are discussed. First, a structure of a semiconductor device of a reference example is described. FIG. 10 is a cross-sectional view depicting the structure of the semiconductor device of the reference example. A semiconductor device 130 of the reference example depicted in FIG. 10 includes, on a single semiconductor substrate (semiconductor chip) 140, a main semiconductor device 110 and a current sensing portion 120 for detecting overcurrent of the main semiconductor device 110. The main semiconductor device 110 is a vertical IGBT having a trench gate structure. The trench gate structure of the main semiconductor device 110 is configured by a p-type base region 102, a carrier storage (CS) region 103, n⁺-type emitter regions 104, p⁺⁺-type contact regions (not depicted), trenches 106, gate insulating films 107, and gate electrodes 108. The main semiconductor device 110 has an emitter electrode 112, the p-type base region 102 and the n⁺-type emitter regions 104 being connected to the emitter electrode 112.

The current sensing portion 120 is a vertical IGBT having cells (function unit of a device) 129 each having a same structure as the structure of a cell 109 of the main semiconductor device 110, the number of the cells 129 being fewer than the number of the cells 109 of the main semiconductor device 110. The trench gate structure of the current sensing portion 120 is configured by a p-type base region 122, a CS region, n⁺-type emitter regions 124, p⁺⁺-type contact regions (not depicted), trenches 126, gate insulating films 127, and gate electrodes 128. The current sensing portion 120 has an emitter electrode 121, the p-type base region 122 and the n⁺-type emitter regions 124 being connected to the emitter electrode 121. The current sensing portion 120 is connected in parallel to the main semiconductor device 110. The emitter electrode 121 of the current sensing portion 120 is connected to an emitter terminal E of an external circuit (not depicted) via a sensing resistor 141 and is fixed at a same potential as a potential of the emitter electrode 112 of the main semiconductor device 110.

In the semiconductor substrate 140, at a front surface thereof, the trench gate structure of the main semiconductor device 110 is provided in an operating region (hereinafter, active-region operating region) 132 of an active region 131, while in a portion (hereinafter, control pad region) 133 of the active region 131 outside the active-region operating region 132, the trench gate structure of the current sensing portion 120 is provided. At a back side of the semiconductor substrate 140, an n⁺-type collector region 113 and a collector electrode 114 common to the main semiconductor device 110 and the current sensing portion 120 are provided. The semiconductor substrate 140 constitutes an n⁻-type drift region 101 common to the main semiconductor device 110 and the current sensing portion 120.

When voltage (forward voltage) that is positive with respect to the emitter electrode 112 of the main semiconductor device 110 is applied to the collector electrode 114 and voltage that is at least equal to a gate threshold voltage is applied to the gate electrodes 108 of the main semiconductor device 110, a main current (drift current) Id flows from the n⁺-type collector region 113 of the main semiconductor device 110 to the n⁺-type emitter regions 104 and the main semiconductor device 110 turns on. Concurrently with conduction of the main semiconductor device 110, under conditions that are the same as conditions of the main semiconductor device 110, a main current (drift current, hereinafter, sensing current) Is flows through the current sensing portion 120 and the current sensing portion 120 turns on.

The sensing current Is flows to the sensing resistor 141 as a result of the sensing current Is flowing through the current sensing portion 120, whereby a voltage drop occurs at the sensing resistor 141. Variation of the voltage at the sensing resistor 141 is monitored by the external circuit, a difference in potential between terminals of the sensing resistor 141 is obtained as the sensing voltage and the sensing current Is (=sensing voltage/resistance value Rs of the sensing resistor 141) of the current sensing portion 120 is calculated. In an instance in which the sensing current Is is a value set in advance, a protective function of the main semiconductor device 110 such as a supply of a gate voltage to the main semiconductor device 110 as overcurrent flowing through the main semiconductor device 110 is suspended, or the like.

As a result, the main semiconductor device 110 is protected during an abnormality such as when the main current Id (short-circuit current) of the main semiconductor device 110 increases and becomes a large current (overcurrent) when the main semiconductor device 110 short circuits (is turned on) or when the main current Id of the main semiconductor device 110 has an excessive current value (overcurrent). However, during a transitional switching period (period when Miller effect occurs) when the IGBTs (the main semiconductor device 110 and the current sensing portion 120) transition from an off state to an on state (turn on), the sensing voltage generated at the sensing resistor 141 increases with the transition and when the IGBT turns on normally, the protective function of the main semiconductor device 110 operates erroneously.

For example, while erroneous operation of the protective function of the main semiconductor device 110 may be prevented by providing a dead time during which a protective operation of the main semiconductor device 110 is non-responsive when the IGBT turns on, the period during which the main semiconductor device 110 short circuits (is on) is prolonged by the non-responsive state of the protective operation of the main semiconductor device 110. During this period, when overcurrent flows through the main semiconductor device 110, the semiconductor device 130 may heat violently or the semiconductor substrate 140 (the semiconductor device 130) may burn and be scorched. Thus, preferably, a dead time during which the protective operation of the main semiconductor device 110 is non-responsive is omitted or is made as short as possible.

Thus, in the present embodiment, enhancement of the protective capability against overcurrent is one example of a problem to be solved.

Embodiments of a semiconductor device according to the present invention is described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical are given the same reference numerals and are not repeatedly described.

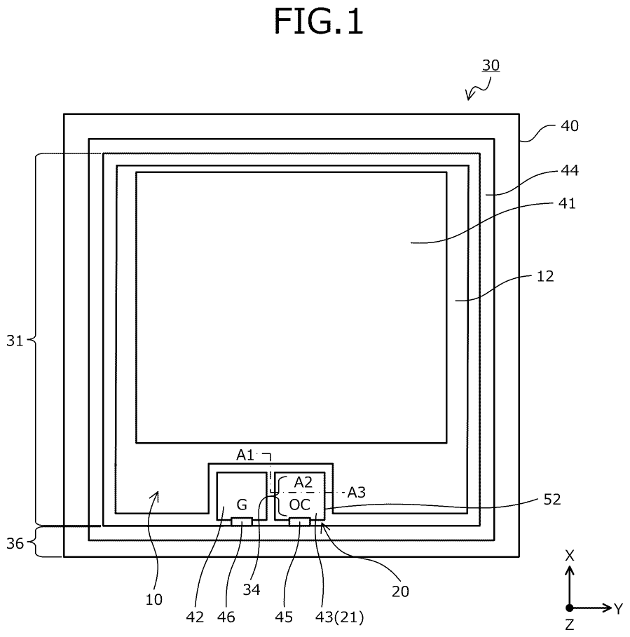

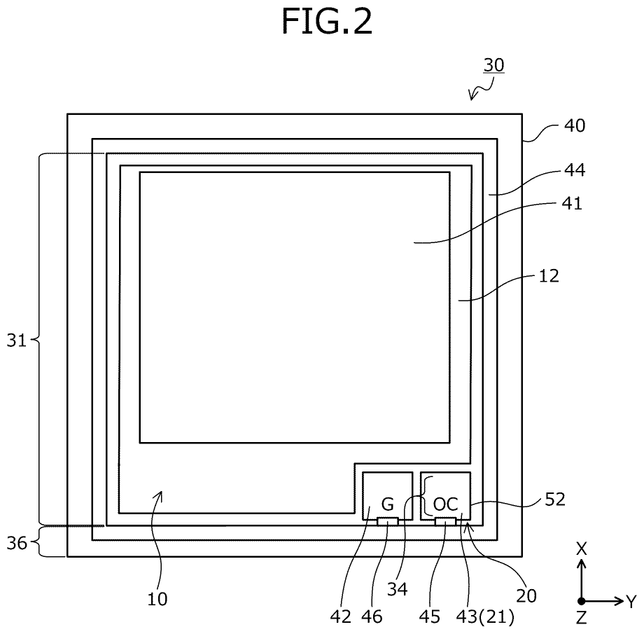

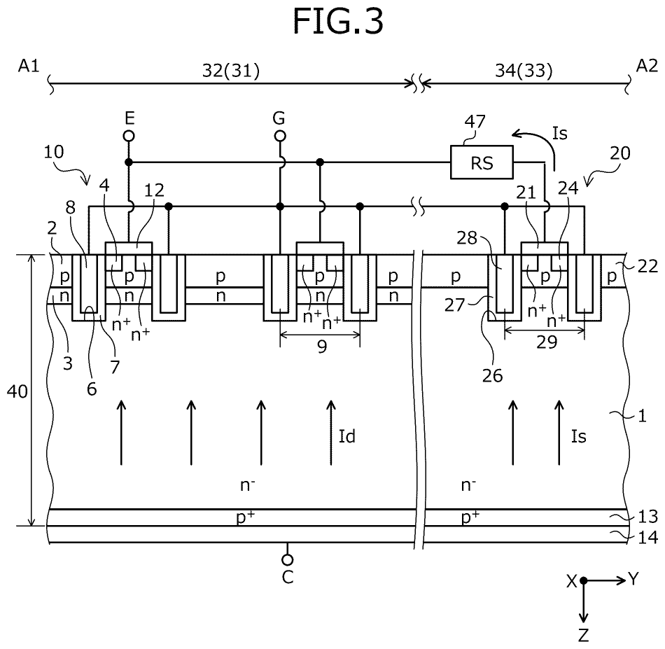

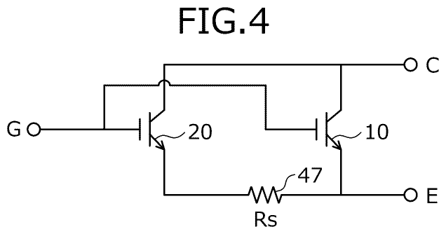

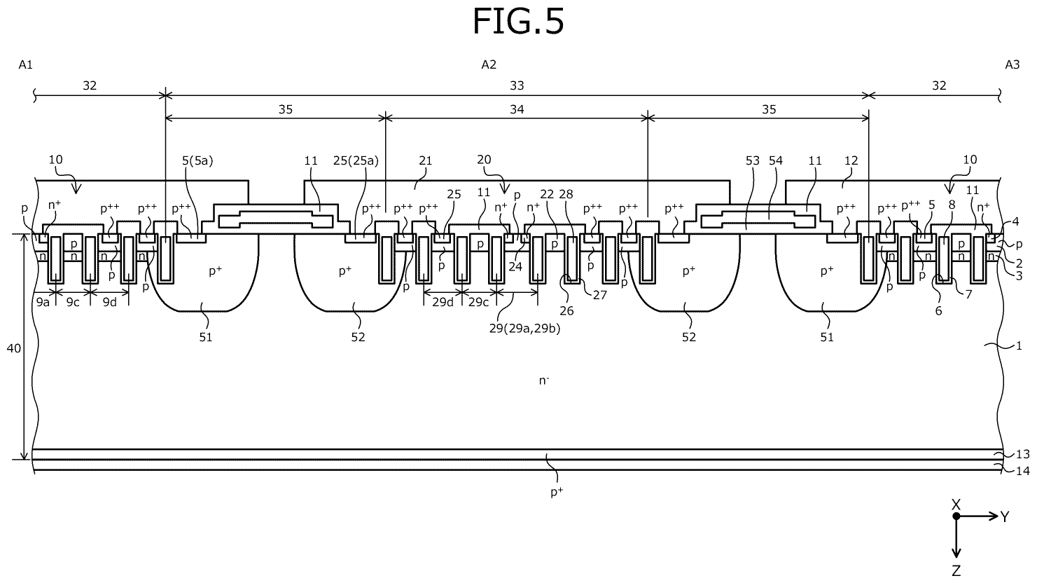

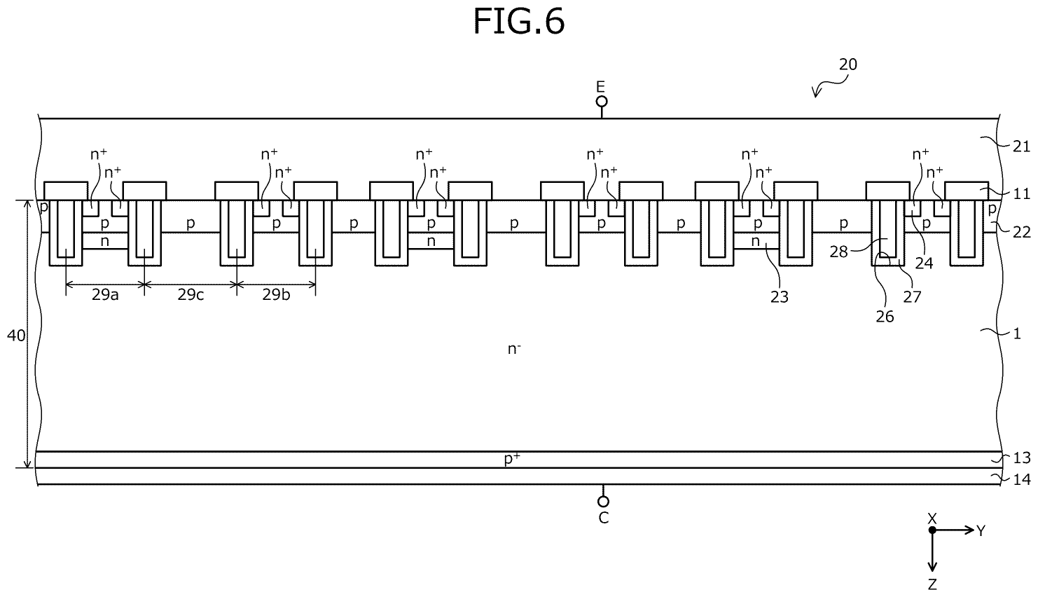

A semiconductor device of a first embodiment solving the problems above is described. FIG. 1 is a plan view depicting a layout when the semiconductor device according to the first embodiment is viewed from a front side of a semiconductor substrate thereof. FIG. 2 is a plan view depicting an example of another layout when the semiconductor device according to the first embodiment is viewed from the front side of the semiconductor substrate thereof. FIG. 3 is a cross-sectional view depicting an overview of the structure along cutting line A1-A2 in FIG. 1. FIG. 4 is a circuit diagram depicting an equivalent circuit of FIG. 3. FIG. 5 is a cross-sectional view depicting, in detail, the structure along cutting line A1-A2-A3 in FIG. 1. FIG. 6 is a cross-sectional view depicting an example of a layout of CS regions of a current sensing portion.

A semiconductor device 30 according to the first embodiment depicted in FIG. 1, for example, is an electronic component mounted to a semiconductor circuit device such as an intelligent power module (IPM) and includes a main semiconductor device (first device) 10 and a high function portion that is a circuit portion for protecting and controlling the main semiconductor device 10. The main semiconductor device 10 is disposed in an operating region (active-region operating region: first device region) 32 of an active region 31 of a semiconductor substrate (semiconductor chip) 40. The main semiconductor device 10 is a vertical IGBT configured by multiple cells 9 (first cells, refer to FIGS. 3 and 5) each having a same structure, the multiple cells 9 being connected in parallel to one another by an emitter electrode 12, and the main semiconductor device 10 performing a main operation of the semiconductor device 30.

The active region 31 has a substantially rectangular shape in a plan view of the device and is provided in substantially a center (chip center) of the semiconductor substrate 40. The active-region operating region 32 is a region through which a main current of the main semiconductor device 10 flows and occupies a majority of the surface area of the active region 31. A portion of the active-region operating region 32, for example, is recessed toward the chip center in a substantially rectangular shape in a plan view of the device. The emitter electrode 12 of the main semiconductor device 10 has substantially a same shape as the shape of the active-region operating region 32 in a plan view of the device and covers nearly an entire surface of the active-region operating region 32. A portion of the emitter electrode 12 exposed in an opening of a passivation film functions as an emitter pad (electrode pad) 41 of the main semiconductor device 10. At the emitter pad 41, the emitter electrode 12 of the main semiconductor device 10 is connected to an emitter terminal E of an external circuit (not depicted) (refer to FIGS. 3 and 4).

A high function portion, for example, a current sensing portion (second device) 20, a temperature sensing portion (not depicted), an overvoltage protecting portion (not depicted), an arithmetic circuit portion (not depicted), etc., disposed in a portion (control pad region) 33 of the active region 31 outside the active-region operating region 32. The control pad region 33 is a region not functioning as the main semiconductor device 10. The control pad region 33 is free of the cells 9 of the main semiconductor device 10. The control pad region 33 may be provided between the active-region operating region 32 and an edge termination region 36 or may be provided in substantially a center of the active region 31 while a periphery of the control pad region 33 is surrounded by the active-region operating region 32 in a plan view of the device.

The control pad region 33, for example, has a substantially rectangular shape in a plan view of the device and is disposed between the active-region operating region 32 and the edge termination region 36, in the recessed portion of the active-region operating region 32, so that three sides thereof (FIG. 1) or two sides thereof (FIG. 2) are bordered by the active-region operating region 32. In the control pad region 33, a gate pad (electrode pad) 42 of the main semiconductor device 10 and electrode pads (in FIGS. 1 and 2, only an OC pad 43 is depicted) of the high function portions are disposed adjacent to one another. The electrode pads of the gate pad 42 and the high function portions, for example, have substantially rectangular shapes in a plan view of the device and are disposed apart from the emitter pad 41 and apart from one another. The gate pad 42 is connected to a gate terminal G of an external circuit.

The current sensing portion 20 is disposed in a later-described sensing region 34 of the control pad region 33. The current sensing portion 20 is a vertical IGBT that has cells 29 (second cells, refer to FIGS. 3 and 5) each having substantially a same structure as the structure of the cells 9 of the main semiconductor device 10, the number of the cells 29 being fewer than the number of the cells 9 of the main semiconductor device 10 (for example, 1/1000 of the number of the cells 9); the current sensing portion 20 contributes to the protective operation for the main semiconductor device 10. Substantially the same structure means the cells 29 include a first group of the cells 29 free of CS regions 23 and thus, having the same structure as the structure of the cells 9 of the main semiconductor device 10 and a second group of the cells 29 having the same structure as the structure of the cells 9 of the main semiconductor device 10 excluding CS regions 3.

The cells 29 of the current sensing portion 20 are connected in parallel by an emitter electrode 21. The current sensing portion 20 is connected in parallel to the main semiconductor device 10. The current sensing portion 20 is operated under the same conditions as conditions of the main semiconductor device 10 and sensing voltage generated at a sensing resistor 47 is measured, whereby overcurrent (OC) flowing through the main semiconductor device 10 may be detected. The emitter electrode 21 of the current sensing portion 20 has substantially a same shape as the shape of the sensing region 34 in a plan view of the device and covers an entire surface of the sensing region 34. The sensing region (second device region) 34 is a region through which a main current of the current sensing portion 20 passes when the current sensing portion 20 is on.

A portion of the emitter electrode 21 of the current sensing portion 20 exposed in an opening of the passivation film functions as an emitter pad (hereinafter, the OC pad) 43 of the current sensing portion 20. At the OC pad 43, the emitter electrode 21 is connected to the emitter terminal E of an external circuit via the sensing resistor 47 (refer to FIGS. 3 and 4). The emitter electrode 21 of the current sensing portion 20 is electrically connected to the emitter electrode 12 of the main semiconductor device 10, via the sensing resistor 47 and the emitter terminal E of the external circuit. The sensing resistor 47 and external circuit are mounted on an IPM together with, for example, the semiconductor device 30 (the semiconductor substrate 40).

In a plan view of the device, the sensing region 34, for example, has a substantially rectangular shape and a periphery of the sensing region 34 is surrounded by an extracting region 35. At least one side of the sensing region 34 (the current sensing portion 20) faces the active-region operating region 32 (the main semiconductor device 10) with the extracting region 35 intervening therebetween; for example, when three sides of the periphery of the control pad region 33 are bordered by the active-region operating region 32 and the sensing region 34 is disposed outermost in the control pad region 33, two sides of the periphery of the sensing region 34 face the active-region operating region 32 with the extracting region 35 intervening therebetween (FIG. 1). When the sensing region 34 is disposed in a corner portion of the active region 31, one or two sides of the periphery of the sensing region 34 faces the active-region operating region 32 with the extracting region 35 intervening therebetween (FIG. 2).

The temperature sensing portion has a function of detecting the temperature of the main semiconductor device 10 (the semiconductor substrate 40) by using temperature characteristics of diodes. The overvoltage protecting portion, for example, is a diode that protects the main semiconductor device 10 from overvoltage (OV) such as surges. The current sensing portion 20, the temperature sensing portion, and the overvoltage protecting portion are controlled by the arithmetic circuit portion. The arithmetic circuit portion controls the main semiconductor device 10, based on signals output from the current sensing portion 20, the temperature sensing portion, and the overvoltage protecting portion. The arithmetic circuit portion is configured by multiple semiconductor devices such as complementary MOS (CMOS) circuits.

The edge termination region 36 is a region between the active region 31 and an end (chip end) of the semiconductor substrate 40; the edge termination region 36 is adjacent to the active region 31 and surrounds a periphery of the active region 31 in a plan view of the device. The edge termination region 36 has a function of mitigating electric field of a front side of the semiconductor substrate 40 and sustaining a breakdown voltage. In the edge termination region 36, for example, a general voltage withstanding structure (not depicted) such as a field limiting ring (FLR), a junction termination extension (JTE) structure, etc. is provided. The breakdown voltage is a voltage limit at which no malfunction or destruction of the semiconductor device occurs.

Further, in the edge termination region 36, a gate runner 44 is disposed between the active region 31 and the voltage withstanding structure. The gate runner 44 surrounds the periphery of the active region 31. The gate runner 44 is configured by a gate polysilicon (poly-Si) wiring layer and a gate metal wiring layer. The gate polysilicon wiring layer of the gate runner 44 is disposed between a field oxide film 53 (refer to FIG. 5) and an interlayer insulating film 11 (refer to FIG. 5). The gate polysilicon wiring layer of the gate runner 44 connects gate electrodes 8 of all the cells 9 of the main semiconductor device 10 and is electrically connected to the gate pad 42 via a gate resistor 46.

Further, gate electrodes 28 of all the cells 29 of the current sensing portion 20 are connected to the gate polysilicon wiring layer of the gate runner 44, via a sensing gate polysilicon layer 54 (refer to FIG. 5) and a gate resistor 45 (refer to FIG. 5). The sensing gate polysilicon layer 54 (refer to FIG. 5) surrounds the periphery of the sensing region 34 in a plan view of the device. The gate resistors 45, 46 are provided in the edge termination region 36 or the extracting region 35, between the field oxide film 53 and the interlayer insulating film 11. The sensing gate polysilicon layer 54 is provided in the extracting region 35, between the field oxide film 53 and the interlayer insulating film 11.

The gate resistors 45, 46 and the sensing gate polysilicon layer 54 are constituted by polysilicon layers provided at a same level as the gate polysilicon wiring layer of the gate runner 44. The gate metal wiring layer of the gate runner 44 is provided on the gate polysilicon wiring layer of the gate runner 44 and is connected to the gate polysilicon wiring layer via a contact hole of the interlayer insulating film 11. The gate metal wiring layer of the gate runner 44 is provided at a same level as electrodes pads other than the electrode pads of the high function portions of the current sensing portion 20, the emitter pad 41, the gate pad 42, and the OC pad 43.

A cross-section of the structure of the semiconductor device 30 according to the first embodiment is described with reference to FIGS. 3, 5, and 6. The semiconductor device 30 according to the first embodiment has, in the active-region operating region 32, a trench gate structure of the main semiconductor device 10, in the semiconductor substrate 40, at a front surface of the semiconductor substrate 40 and has, in the sensing region 34 of the control pad region 33, a trench gate structure of the current sensing portion 20, in the semiconductor substrate 40, at the front surface of the semiconductor substrate 40. The semiconductor substrate 40 is an n⁻-type bulk substrate constituting an n⁻-type drift region (first semiconductor region) 1 common to the main semiconductor device 10 and the current sensing portion 20. A semiconductor material of the semiconductor substrate 40, for example, is silicon (Si) or silicon carbide (SIC).

The trench gate structure of the main semiconductor device 10 is configured by p-type base regions (third semiconductor regions) 2, the CS regions (first storage regions) 3, n⁺-type emitter regions (fourth semiconductor regions) 4, p⁺⁺-type contact regions 5, trenches (first trenches) 6, gate insulating films (first gate insulating films) 7, and gate electrodes (first gate electrodes) 8. The p-type base regions 2, the CS regions 3, the n⁺-type emitter regions 4, and the p⁺⁺-type contact regions 5 are diffused regions formed by ion implantation in the semiconductor substrate 40 and are provided between the front surface of the semiconductor substrate 40 and the n⁻-type drift region 1. The p-type base regions 2 are provided in an entire area of the active-region operating region 32, between the front surface of the semiconductor substrate 40 and the n⁻-type drift region 1.

Each of the CS regions 3 is provided in an entire area between a corresponding adjacent two of the trenches 6, the CS regions 3 being between and in contact with the p-type base regions 2 and the n⁻-type drift region 1 and reaching sidewalls of the trenches 6. The CS regions 3, for example, are diffused regions formed by ion implantation of an n-type dopant such as phosphorus (P) or arsenic (As) by a high acceleration energy. The CS regions 3 are n-type regions with a doping concentration that is higher than a doping concentration of the n⁻-type drift region 1; the CS regions 3 constitute a minority carrier (hole) barrier and have a function of storing minority carriers. A doping concentration is a concentration of some impurity atoms (dopant) that are intentionally added to region/layers. The CS regions 3 are disposed in all the cells 9 of the main semiconductor device 10. Due to the CS regions 3, an injection enhancement ((IE) electron injection enhancement) effect is increased and the conductivity modulation effect is increased, whereby on-voltage Von of the cells 9 is decreased.

The n⁺-type emitter regions 4 and the p⁺⁺-type contact regions 5 are each selectively provided between the front surface of the semiconductor substrate 40 and the p-type base regions 2. The n⁺-type emitter regions 4 and the p⁺⁺-type contact regions 5 each have a lower surface (surface facing a later-described n⁺-type collector region 13) and are in contact with the p-type base regions 2 at the lower surface while at an upper surface thereof (the front surface of the semiconductor substrate 40), are in contact with the emitter electrode (first electrode) 12. The n⁺-type emitter regions 4 and the p-type base regions 2 are adjacent to the sidewalls of the trenches 6. The p⁺⁺-type contact regions 5 may be omitted. In this instance, instead of the p⁺⁺-type contact regions 5, the p-type base regions 2 reach the front surface of the semiconductor substrate 40.

The trenches 6 penetrate through the n⁺-type emitter regions 4 and the p-type base regions 2 in a depth direction Z from the front surface of the semiconductor substrate 40 and terminate in the n⁻-type drift region 1. In portions where the CS regions 3 are provided, the trenches 6 also penetrate through the CS regions 3. The trenches 6, for example, extend linearly in a first direction X that is parallel to the front surface of the semiconductor substrate 40 and are arranged forming a striped pattern in which the trenches 6 are adjacent to one another in a second direction Y that is parallel to the front surface of the semiconductor substrate 40 and orthogonal to the first direction X. In the trenches 6, the gate electrodes 8 are provided via the gate insulating films 7, respectively. Between each adjacent two of the trenches 6 in the second direction Y (between centers of each of the adjacent two), one of the cells 9 is configured.

The p-type base regions 2, the CS regions 3, the n⁺-type emitter regions 4, and the p⁺⁺-type contact regions 5 each have a uniform thickness, extend linearly in the first direction X between each adjacent two of the trenches 6, and have a length substantially a same as a length of each of the trenches 6 in a longitudinal direction (the first direction X) of the trenches 6. A portion of the semiconductor substrate 40 other than the trench gate structure of the main semiconductor device 10, the trench gate structure of the current sensing portion 20, later-described p⁺-type regions 51, 52, diffused regions (not depicted) formed in the semiconductor substrate 40, at the front surface thereof in the edge termination region 36, and the later-described n⁺-type collector region 13 at the back surface of the semiconductor substrate 40, constitutes the n⁻-type drift region 1.

Of the cells 9 of the main semiconductor device 10, some of the cells 9 may be cells 9c that are free of the n⁺-type emitter regions 4. The p-type base regions 2 of the cells 9c that are free of the n⁺-type emitter regions 4 may be electrically insulated from the emitter electrode 12 by the interlayer insulating film 11 and electrically floating (refer to FIG. 5), or may be electrically connected to the emitter electrode 12 via the p⁺⁺-type contact regions 5, or may be connected directly to the emitter electrode 12 and thereby, fixed to the potential of the emitter electrode 12 (not depicted). The cells 9c that are free of the n⁺-type emitter regions 4 do not contribute to IGBT operation of the main semiconductor device 10.

When the p-type base regions 2 of the cells 9c that are free of the n⁺-type emitter regions 4 are electrically floating and the main semiconductor device 10 turns on, minority carriers near the p-type base regions 2 in the n⁻-type drift region 1 are not easily swept out to the emitter electrode 12 and thus, the IE effect in the active-region operating region 32 increases. On the other hand, when the p-type base regions 2 of the cells 9c that are free of the n⁺-type emitter regions 4 are fixed to the potential of the emitter electrode 12 and the main semiconductor device 10 turns off, minority carriers in the n⁻-type drift region 1 are easily swept out to the emitter electrode 12 and local concentration of electric field in the active-region operating region 32 may be suppressed.

The cells 9a (the cells contributing to the IGBT operation of the main semiconductor device 10) in which the n⁺-type emitter regions 4 are disposed and the cells 9c that are free of the n⁺-type emitter regions 4 are disposed repeatedly at constant intervals. Of the cells 9 of the main semiconductor device 10, cells 9d that are disposed in an outer peripheral portion (portion facing the control pad region 33 and the edge termination region 36) of the active-region operating region 32 may be configured to be free of the n⁺-type emitter regions 4 and to have the p⁺⁺-type contact regions 5 and the p-type base regions 2 fixed to the potential of the emitter electrode 12. In this instance, the cells 9d of the outer peripheral portion of the active-region operating region 32 do not contribute to the IGBT operation of the main semiconductor device 10.

The interlayer insulating film 11 is provided in an entire area of the front surface of the semiconductor substrate 40 and covers the gate electrodes 8 of all the cells 9 of the main semiconductor device 10 and the gate electrodes 28 of all the cells 29 of the current sensing portion 20. Further, the interlayer insulating film 11 covers the sensing gate polysilicon layer 54 of the extracting region 35 of the control pad region 33 and a gate polysilicon layer (not depicted) configuring the gate runner 44 of the edge termination region 36. The emitter electrode 12 is provided on the interlayer insulating film 11 in the active-region operating region 32, forms an ohmic contact with the semiconductor substrate 40 in contact holes of the interlayer insulating film 11, and is electrically connected to the n⁺-type emitter regions 4, the p⁺⁺-type contact regions 5, and the p-type base regions 2.

The emitter electrode 12 extends to the extracting region 35 of the control pad region 33 and terminates on the interlayer insulating film 11 in the extracting region 35. The front surface of the semiconductor substrate 40 is protected by the passivation film (not depicted). Openings in the passivation film expose different electrode pads, respectively. Between the back surface of the semiconductor substrate 40 and the n⁻-type drift region 1, the n⁺-type collector region (second semiconductor region) 13, which is common to the main semiconductor device 10 and the current sensing portion 20, is provided in contact with the n⁻-type drift region 1. The n⁺-type collector region 13, for example, is a diffused region formed by ion implantation in the semiconductor substrate 40. Between the n⁻-type drift region 1 and the n⁺-type collector region 13, an n-type field stop layer having a doping concentration higher than the doping concentration of the n⁻-type drift region 1 may be provided. A collector electrode (back electrode) 14 is provided in an entire area of the back surface of the semiconductor substrate 40 and is electrically connected to the n⁺-type collector region 13. The collector electrode 14 is connected to a collector terminal C of an external circuit.

The trench gate structure of the current sensing portion 20 is formed concurrently with the trench gate structure of the main semiconductor device 10, and is configured by p-type base regions (fifth semiconductor regions) 22, CS regions (second storage regions) 23, n⁺-type emitter regions (sixth semiconductor regions) 24, p⁺⁺-type contact regions 25, trenches (second trenches) 26, gate insulating films (second gate insulating films) 27, and gate electrodes (second gate electrodes) 28. Configuration of the p-type base regions 22, the n⁺-type emitter regions 24, the p⁺⁺-type contact regions 25, the trenches 26, the gate insulating films 27, and the gate electrodes 28 of the current sensing portion 20 is a same as the configuration of the p-type base regions 2, the n⁺-type emitter regions 4, the p⁺⁺-type contact regions 5, the trenches 6, the gate insulating films 7, and the gate electrodes 8 of the main semiconductor device 10.

Arrangement of the CS regions 23 of the current sensing portion 20 differs from arrangement of the CS regions 3 of the main semiconductor device 10, and intervals between the CS regions 23 in the sensing region 34 are relatively larger. In particular, the p-type base regions 22 are provided in an entire area between the front surface of the semiconductor substrate 40 and the n⁻-type drift region 1 in the sensing region 34. Each of the CS regions 23 is disposed between predetermined adjacent trenches of the trenches 26, in an entire area between the n⁻-type drift region 1 and the p-type base regions 22, the CS regions 23 being provided in contact with these regions and reaching the sidewalls of the trenches 26. The CS regions 23 are n-type regions with a doping concentration that is higher than the doping concentration of the n⁻-type drift region 1, constitute a minority carrier barrier, and have a function of storing minority carriers.

The CS regions 23 are disposed in some of the cells 29 in the current sensing portion 20, whereby intervals between the CS regions 23 are relatively larger in the sensing region 34. As a result, an average carrier concentration (concentration of activated n-type dopant) of the CS regions 23 per unit area of the sensing region 34 is lower than an average carrier concentration of the CS regions 3 per unit area of the active-region operating region 32. Similar to the cells 9 of the main semiconductor device 10, the on-voltage Von is reduced by the cells 29 in which the CS regions 23 are disposed; however, the IE effect is inhibited by the cells 29 that are free of the CS regions 23 and on-characteristics of the current sensing portion 20 become lower than on-characteristics of the main semiconductor device 10.

For example, in an instance in which the CS regions 23 are not disposed in all the cells 29 contributing to the IGBT operation of the current sensing portion 20, there is a tendency for rapid switching (dV/dt becomes steep) during turn off of the current sensing portion 20, and when the sensing current Is of the current sensing portion 20 is interrupted under high-speed switching conditions, there is a risk of destruction even when the current sensing portion 20 is within a range of specifications. On the other hand, in the first embodiment, the CS regions 23 are disposed in the sensing region 34 with relatively larger intervals therebetween, whereby increases in the sensing voltage are suppressed to a certain extent when the IGBTs (the main semiconductor device 10 and the current sensing portion 20) turn on and tolerance against destruction with respect to dV/dt (rate of change over time) of voltage between the emitter and collector of the current sensing portion 20 when the IGBT turns on is enhanced.

The average carrier concentration of the CS regions 23 per unit area of the sensing region 34 suffices to be about 0.2 times to 0.6 times the average carrier concentration of the CS regions 3 per unit area of the active-region operating region 32. The average carrier concentrations of the CS regions 3, 23 per unit area are values, respectively, obtained by dividing respective total dose amounts (total charge amounts) of an n-type dopant ion-implanted and activated to form the CS regions 3, 23 in the active-region operating region 32 and the sensing region 34, respectively, by the thicknesses of the CS regions 3, 23 and the respective areas of the active-region operating region 32 and the sensing region 34. As described hereinafter, preferably, cells 29a in which the CS regions 23 are disposed and cells 29b that are free of the CS regions 23 are disposed repeatedly at a constant period.

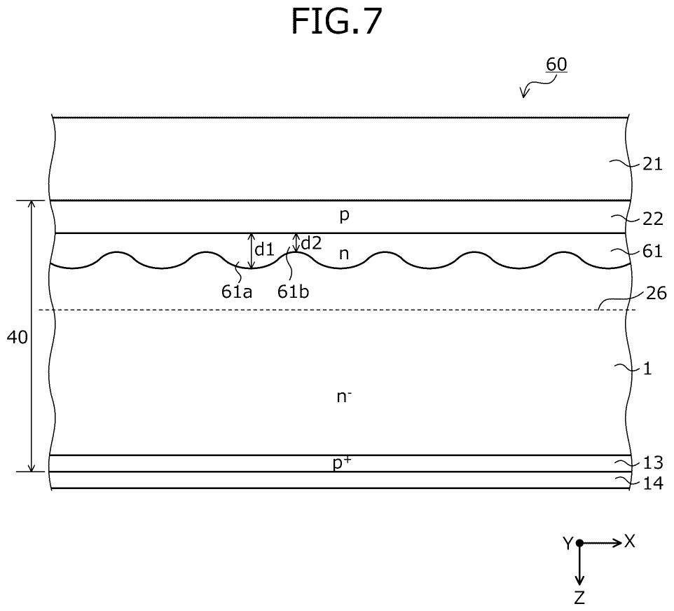

A maximum carrier concentration of the CS regions 23 may be substantially a same as a maximum carrier concentration of the CS regions 3 of the active-region operating region 32 or may be lower than the maximum carrier concentration of the CS regions 3 of the active-region operating region 32. For example, concurrent formation of the CS regions 3 of the active-region operating region 32 and the CS regions 23 of the sensing region 34 enables the maximum carrier concentrations of the CS regions 3, 23 to be made substantially the same. Substantially the same carrier concentration means a same doping concentration in a range including an allowable error due to process variation. A method of making the maximum carrier concentration of the CS regions 23 lower than the maximum carrier concentration of the CS regions 3 of the active-region operating region 32 is described hereinafter (refer to FIGS. 7 to 9).

The n⁺-type emitter regions 24 and the p⁺⁺-type contact regions 25 are each selectively provided between the front surface of the semiconductor substrate 40 and the p-type base regions 22. The n⁺-type emitter regions 24 and the p⁺⁺-type contact regions 25 each have a lower surface and is contact with the p-type base regions 22 at the lower surface while at the front surface of the semiconductor substrate 40, are in contact with the emitter electrode (second electrode) 21. The n⁺-type emitter regions 24 and the p-type base regions 22 are adjacent to the sidewalls of the trenches 26. The p⁺⁺-type contact regions 25 may be omitted. In this instance, instead of the p⁺⁺-type contact regions 25, the p-type base regions 22 reach the front surface of the semiconductor substrate 40.

The trenches 26 penetrate through the n⁺-type emitter regions 24 and the p-type base regions 22 in the depth direction Z from the front surface of the semiconductor substrate 40 and terminate in the n⁻-type drift region 1. In portions where the CS regions 23 are provided, the trenches 26 further penetrate through the CS regions 23. The trenches 26 are disposed in plural forming a striped pattern parallel to the trenches 6 of the main semiconductor device 10. In the trenches 26, the gate electrodes 28 are provided via the gate insulating films 27, respectively. The p-type base regions 22, the CS regions 23, the n⁺-type emitter regions 24, and the p⁺⁺-type contact regions 25 each have a uniform thickness, extends linearly in the first direction X between the trenches 26 adjacent to one another, and have a length substantially a same as a length of each of the trenches 26 in the longitudinal direction (the first direction X) of the trenches 26.

Between each adjacent two of the trenches 26 in the second direction Y (between centers of each of the adjacent two), one of the cells 29 is configured. Of the cells 29 in which the n⁺-type emitter regions 24 are disposed, some of the cells 29 may be the cells 29b free of the CS regions 23. As a result, the average carrier concentration of the CS regions 23 per unit area of the current sensing portion 20 is lower than the average carrier concentration of the CS regions 3 per unit area of the main semiconductor device 10. Some of the cells 29 contributing to the IGBT operation of the current sensing portion 20 are free of the CS regions 23, whereby the on-characteristics of the current sensing portion 20 are reduced. Preferably, of the cells 29 (29a, 29b) in which the n⁺-type emitter regions 24 are disposed, the cells 29a in which the CS regions 23 are disposed (third cells) and the cells 29b that are free of the CS regions 23 (fourth cells) are disposed repeatedly at a constant period.

Some of the cells 29 of the current sensing portion 20 may be the cells 29c that are free of the n⁺-type emitter regions 24. The p-type base regions 22 of the cells 29c that are free of the n⁺-type emitter regions 24 may be electrically insulated from the emitter electrode 12 by the interlayer insulating film 11 and may be electrically floating (refer to FIG. 5), or may be electrically connected to the emitter electrode 12 via the p⁺⁺-type contact regions 25, or may be connected directly to the emitter electrode 12 and thereby, fixed to the potential of the emitter electrode 12 (refer to FIG. 6). The cells 29c that are free of the n⁺-type emitter regions 24 do not contribute to the IGBT operation of the current sensing portion 20.

The cells 29 (29a, 29b) in which the n⁺-type emitter regions 24 are disposed and the cells 29c that are free of the n⁺-type emitter regions 24 are disposed repeatedly at a constant period. In particular, for example, when, of the cells 29 (29a, 29b) in which the n⁺-type emitter regions 24 are disposed, a set of the cells 29a in which the CS regions 23 are disposed and a set of the cells 29b that are free of the CS regions 23 are disposed repeatedly alternating one another, each of the sets having a same number of cells (in FIG. 6, each set contains one cell), in this instance, between any two of the sets of the cells 29a, 29b adjacent to each other, between any adjacent two of the cells 29a, between any adjacent two of the cells 29b, the cells 29c that are free of the n⁺-type emitter regions 24 are disposed at a constant period (for example, one of the cells 29c is disposed for each adjacent two) (refer to FIG. 6).

Some of the cells 29c of the cells 29 (cells not contributing to the IGBT operation of the current sensing portion 20) free of the n⁺-type emitter regions 24 may be free of the CS regions 23. When the p-type base regions 22 of the cells 29c that are free of the n⁺-type emitter regions 24 are floating electrically, minority carriers near the p-type base regions 22 in the n⁻-type drift region 1 are not easily swept to the emitter electrode 12 when the current sensing portion 20 turns on. Thus, the IE effect in the sensing region 34 is increased by the cells 29c independent of whether the CS regions 23 are disposed in the cells 29c.

On the other hand, when the p-type base regions 22 of the cells 29c that are free of the n⁺-type emitter regions 24 are fixed to the potential of the emitter electrode 21, the minority carriers in the n⁻-type drift region 1 when the current sensing portion 20 turns off are easily swept to the emitter electrode 21 and local concentration of electric field in the sensing region 34 may be suppressed. Further, when the p-type base regions 22 of the cells 29c that are free of the n⁺-type emitter regions 24 are fixed to the potential of the emitter electrode 21, preferably, the cells 29c may be free of the CS regions 23. The cells 29c being free of the CS regions 23, similar to the cells 29b, enables inhibition of the IE effect in the sensing region 34.

Of the cells 29 of the current sensing portion 20, cells 29d that are disposed in an outer peripheral portion (portion facing the extracting region 35) of the sensing region 34 may be configured to be free of the n⁺-type emitter regions 24 with the p⁺⁺-type contact regions 25 and the p-type base regions 22 being fixed to the potential of the emitter electrode 12. In this instance, the cells 29d of the outer peripheral portion of the sensing region 34 do not contribute to the IGBT operation of the main semiconductor device 10. Preferably, the cells 29d disposed in the peripheral portion of the sensing region 34, at portions of the sensing region 34 facing the active-region operating region 32 with the extracting region 35 intervening therebetween, are free of the CS regions 23.

When the IGBT turns off, minority carriers in the n⁻-type drift region 1 in the active-region operating region 32 flow through the p-type base regions 22 that are at the portions of the sensing region 34 facing the active-region operating region 32. Thus, preferably, the cells 29d that are in the peripheral portion of the sensing region 34, at portions of the sensing region 34 facing the active-region operating region 32, are free of the CS regions 23. As a result, the IE effect in the peripheral portion of the sensing region 34 is inhibited and the conductivity modulation effect decreases, whereby the flow of hole current from the active-region operating region 32 to the sensing region 34 when the IGBT turns off may be prevented.

Further, preferably, the CS regions 23 are disposed at a constant period independent of the arrangement of the cells 29a, 29b, 29c (refer to FIG. 6). Disposal of the CS regions 23 at a constant period enables suppression of imbalances of breakdown voltage at the surface of the sensing region 34. On the other hand, when the CS regions 23 are disposed at a relatively larger interval at the surface of the sensing region 34, decreases in the breakdown voltage may occur due to an imbalance of electric field at the surface of the semiconductor substrate 40; however, as described hereinafter, the p⁺-type region 51 of the extracting region 35 isolates pn junctions of the sensing region 34 from pn junctions of other regions, whereby electric field concentration and current concentration at the sensing region 34 may be suppressed.

Configuration other than the arrangement (i.e., disposal at a relatively larger interval) of the CS regions 23 of the current sensing portion 20 is a same as the configuration of the CS regions 3 of the main semiconductor device 10. While FIGS. 3 and 5 depict an instance in which of the cells 9 of the main semiconductor device 10, the cells 9a having the n⁺-type emitter regions 4 and the cells 9c that are free of the n⁺-type emitter regions 4 are disposed adjacent to and repeatedly alternating one another, the arrangement of the cells 9 (9a, 9c) of the main semiconductor device 10 may be suitably set. In FIGS. 3 and 5, depiction of the current sensing portion 20 is simplified, only one of the cells 29 is depicted, and the CS regions 23 are not depicted. An example of a layout of the CS regions 23 is depicted in FIG. 6.

The emitter electrode 21 is provided on the interlayer insulating film 11 in the sensing region 34, is in ohmic contact with the semiconductor substrate 40 in contact holes of the interlayer insulating film 11, and is electrically connected to the n⁺-type emitter regions 24, the p⁺⁺-type contact regions 25, and the p-type base regions 22. The emitter electrode 21 extends to the extracting region 35 of the control pad region 33 and terminates at a position apart from the emitter electrode 12, on the interlayer insulating film 11 in the extracting region 35. The emitter electrode 21 is connected to the emitter terminal E of the external circuit via the sensing resistor 47 and is fixed to the potential of the emitter electrode 12 of the main semiconductor device 10 (FIGS. 3 and 4).

In the extracting region 35 of the control pad region 33, the p⁺-type regions 51, 52 are each selectively provided between the front surface of the semiconductor substrate 40 and the n⁻-type drift region 1 and are in contact with the n⁻-type drift region 1. The p⁺-type regions 51, 52 are disposed apart from one another and surround the periphery of the sensing region 34 in concentric shapes. Between the p⁺-type regions 51, 52 that are adjacent to one another, the n⁻-type drift region 1 reaches the front surface of the semiconductor substrate 40. The p⁺-type regions 51, 52 are electrically connected to the emitter electrodes 12, 21 and have a function of pulling out minority carriers (holes) in the n⁻-type drift region 1 when the IGBT (a semiconductor device 60) is off.

Devices of the main semiconductor device 10 and the current sensing portion 20 are isolated (respective pn junctions thereof are isolated) by a pn junction between the p⁺-type region 51 and the n⁻-type drift region 1 and a pn junction between the p⁺-type region 52 and the n⁻-type drift region 1. The p⁺-type regions 51, 52 are connected to a p⁺-type region (not depicted) directly beneath the gate runner 44 of the edge termination region 36. The p⁺-type region directly beneath the gate runner 44 is disposed at the front surface of the semiconductor substrate 40 and the n⁻-type drift region 1 in the edge termination region 36, faces the gate runner 44 with the field oxide film 53 intervening therebetween, and borders the periphery of the active region 31 in a plan view of the device.

In a portion of the extracting region 35, the portion facing the active-region operating region 32 (in one side of the extracting region 35, opposite the other side thereof facing the sensing region 34), the p⁺-type region 51 is provided. The p⁺-type region 51, at a portion thereof adjacent to the active-region operating region 32, surrounds an outer periphery of the active-region operating region 32 in a plan view of the device. In the depth direction Z from the front surface of the semiconductor substrate 40, the p⁺-type region 51 terminates closer to the n⁺-type collector region 13 than are the trenches 6 of the active-region operating region 32. The p⁺-type region 51 is electrically connected to the emitter electrode 12 of the main semiconductor device 10 via a contact hole of the interlayer insulating film 11. The p⁺⁺-type contact regions 5 (5a) may be provided between and in contact with the p⁺-type region 51 and the emitter electrode 12.

The p⁺-type region 51, at portions thereof adjacent to the active-region operating region 32 in the first direction X, is in contact with the p-type base regions 2 and the CS regions 3 of the active-region operating region 32 and borders longitudinal ends (ends in the first direction X) of the trenches 6 of the active-region operating region 32 (the main semiconductor device 10) (not depicted). The p⁺-type region 51, at portions thereof adjacent to the active-region operating region 32 in the second direction Y (lateral direction of the trenches 6), borders peripheries of closest ones of the trenches 6, the closest ones being closest to the extracting region 35, among the trenches 6 of the active-region operating region 32. The p⁺-type region 51 extends farther into the active-region operating region 32 than are the closest ones of the trenches 6 closest to the extracting region 35 in the second direction Y, among the trenches 6 of the active-region operating region 32 and may be in contact with the p-type base regions 2 and the CS regions 3.

The p⁺-type region 52 is provided in a portion of the extracting region 35 facing the sensing region 34. The p⁺-type region 52 surrounds an outer periphery of the sensing region 34 in a plan view of the device. In the depth direction Z from the front surface of the semiconductor substrate 40, the p⁺-type region 52 terminates closer to the n⁺-type collector region 13 than are the trenches 26 of the sensing region 34 (the current sensing portion 20). The p⁺-type region 52 is electrically connected to the emitter electrode 21 of the current sensing portion 20 via a contact hole of the interlayer insulating film 11. The p⁺⁺-type contact regions 25 (25a) may be provided between and in contact with the p⁺-type region 52 and the emitter electrode 21.

The p⁺-type region 52 is in contact with the p-type base regions 22 and the CS regions 23 of the sensing region 34 in the first direction X and borders adjacent longitudinal ends (ends in the first direction X) of the trenches 26 of the sensing region 34 (not depicted). The p⁺-type region 52, at portions thereof adjacent to the sensing region 34 in the second direction Y (lateral direction of the trenches 26), borders peripheries of closest ones of the trenches 26, the closest ones being closest to the extracting region 35, among the trenches 26. The p⁺-type region 52 extends farther into the sensing region 34 in the second direction Y than are the closest ones of the trenches 26 closest to the extracting region 35 and may be in contact with the p-type base regions 22 (and the CS regions 23 in an instance in which the CS regions 23 are disposed in the cells 29d).

In the extracting region 35, the sensing gate polysilicon layer 54 containing a polysilicon (poly-Si) is disposed on the front surface of the semiconductor substrate 40, via the field oxide film 53. The sensing gate polysilicon layer 54 covers substantially an entire area of the extracting region 35, via the field oxide film 53. The sensing gate polysilicon layer 54 connects the gate electrodes 28 of all the cells 29 in the current sensing portion 20 and is electrically connected to the gate polysilicon wiring layer of the gate runner 44 via the gate resistor 45. The emitter electrodes 12, 21 extend on the sensing gate polysilicon layer 54 with the interlayer insulating film 11 intervening therebetween.

Operation of the semiconductor device 30 according to the first embodiment is described. When voltage (forward voltage) that is positive with respect to the emitter electrode 12 of the main semiconductor device 10 (the emitter pad 41) is applied to the collector electrode 14 and voltage at least equal to the gate threshold voltage is applied to the gate electrodes 8 of the main semiconductor device 10, in the main semiconductor device 10, in portions of the p-type base regions 2 along the trenches 6, channels (n-type inversion layer) are formed. As a result, the main current (drift current) Id flows from the n⁺-type collector region 13 of the main semiconductor device 10, through the channels and to the n⁺-type emitter regions 4, whereby the main semiconductor device 10 turns on.

Under conditions a same as the conditions of the main semiconductor device 10, when voltage (forward voltage) that is positive with respect to the emitter electrode 21 of the current sensing portion 20 (the OC pad 43) is applied to the collector electrode 14 and voltage that is at least equal to the gate threshold voltage is applied to the gate electrodes 28 of the current sensing portion 20, in the sensing region 34, in portions of the p-type base regions 22 along the trenches 26, channels (n-type inversion layer) are formed. As a result, the main current (drift current, hereinafter, the sensing current) Is flows from the n⁺-type collector region 13 of the current sensing portion 20 to the n⁺-type emitter regions 24 and the current sensing portion 20 turns on.

The sensing current Is flows to the current sensing portion 20, whereby a voltage drop occurs at the sensing resistor 47 connected between the emitter electrode 12 of the main semiconductor device 10 and the emitter electrode 21 of the current sensing portion 20. The sensing current Is of the current sensing portion 20 increases according to a magnitude of the main current Id flowing to the main semiconductor device 10 and the voltage drop at the sensing resistor 47 also increases. Variation of the voltage at the sensing resistor 47, for example, is monitored and obtained by an external circuit and the sensing current Is of the current sensing portion 20 is calculated, whereby overcurrent flowing through the main semiconductor device 10 is detected.

In particular, the external circuit obtains the magnitude (difference in potential between the ends of the sensing resistor 47) of voltage drops at the sensing resistor 47 as the sensing voltage and based on this sensing voltage, calculates the sensing current Is of the current sensing portion 20 (=sensing voltage/the resistance value Rs of the sensing resistor 47). Further, assuming overcurrent is flowing through the main semiconductor device 10 in an instance in which the sensing current Is of the current sensing portion 20 exceeds a predetermined value, the external circuit or a high function portion provided on the semiconductor substrate 40 protects the main semiconductor device 10 by suspending supply of the gate voltage to the main semiconductor device 10 or the like.

As a result, destruction of the main semiconductor device 10 may be prevented when an abnormality occurs such as when the main semiconductor device 10 short-circuits, the main current Id (short-circuit current) of the main semiconductor device 10 increases becoming a large current (overcurrent) that exceeds a prescribed value, or when the main current Id of the main semiconductor device 10 has an excessive current value (overcurrent). Preferably, the resistance value Rs of the sensing resistor 47 may be as low as possible. By setting the resistance value Rs of the sensing resistor 47 (for example, 2 kΩ) to be relatively low, power loss occurring due to the sensing current Is flowing through the sensing resistor 47 and generation of heat by the sensing resistor 47 may be suppressed.

When the IGBTs (the main semiconductor device 10 and the current sensing portion 20) turn on, as compared to the main semiconductor device 10, conductivity modulation at the current sensing portion 20 becomes delayed and a rising edge of the sensing current Is becomes delayed, whereby increases of the sensing voltage when the IGBT turns on may be suppressed to a certain extent. As a result, erroneous operation of a protective function of the main semiconductor device 10 when the IGBT turns on normally may be suppressed. Further, a dead time during which a protective operation of the main semiconductor device 10 is non-responsive is eliminated or may be shortened and thus, even when the main semiconductor device 10 turns on rapidly, overcurrent flowing through the main semiconductor device 10 may be detected.

On the other hand, when the voltage applied to the gate electrodes 8 is less than the gate threshold voltage, pn junctions between the p-type base regions 2, the CS regions 3, and the n⁻-type drift region 1 are reverse biased and thus, the main semiconductor device 10 maintains the off-state. Similar to the main semiconductor device 10, voltage less than the gate threshold voltage is also applied to the gate electrodes 28 of the current sensing portion 20. The pn junctions between the p-type base regions 22, the CS regions 23, and the n⁻-type drift region 1 are reverse biased and thus, the current sensing portion 20 also maintains the off-state. At this time, a predetermined breakdown voltage is ensured by the spreading of a depletion layer in the n⁻-type drift region 1, from the pn junctions.

As described, according to the first embodiment, the average carrier concentration of the CS regions per unit area of the sensing region is set to be lower than the average carrier concentration of the CS regions per unit area of the active-region operating region, whereby on-characteristics of the current sensing portion may be reduced more than the on-characteristics of the main semiconductor device. As a result, when the IGBTs (the main semiconductor device and the current sensing portion) turn on, the conductivity modulation at the current sensing portion is delayed relative to the main semiconductor device and a rising edge of the sensing current may be delayed, whereby increases in the sensing voltage when the IGBT turns on may be suppressed to a certain extent.

Thus, erroneous operation of a protective function of the main semiconductor device when the IGBT turns on normally may be suppressed and the protective capability of the main semiconductor device may be enhanced. On the other hand, increases in the sensing voltage when the IGBT turns on may be suppressed, whereby a steady-state sensing voltage (sensing voltage during normal operation of the main semiconductor device) decreases; however, a detection threshold value (lower limit value) for overcurrent flowing through the main semiconductor device is suitably set at the external circuit that monitors voltage changes at the sensing resistor, whereby erroneous operation of a protective function of the main semiconductor device when the IGBT turns on normally may be suppressed.

Further, increases in the sensing voltage when the IGBT turns on may be suppressed to a certain extent, whereby a dead time during which a protective operation of the main semiconductor device is non-responsive may be eliminated or may be shortened. As a result, during a state when a protective operation of the main semiconductor device is non-responsive, a period during which the main semiconductor device short-circuits (is on) is eliminated or may be shortened, whereby even in an instance of a design condition for the main semiconductor device to turn on rapidly, during an abnormality in which overcurrent flows through the main semiconductor device, the overcurrent is detected and the main semiconductor device may protected. Thus, saturation characteristics of the main semiconductor device may be improved.

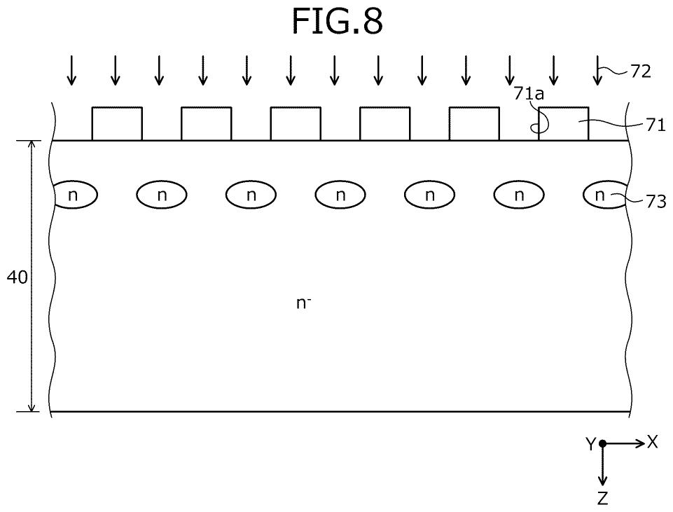

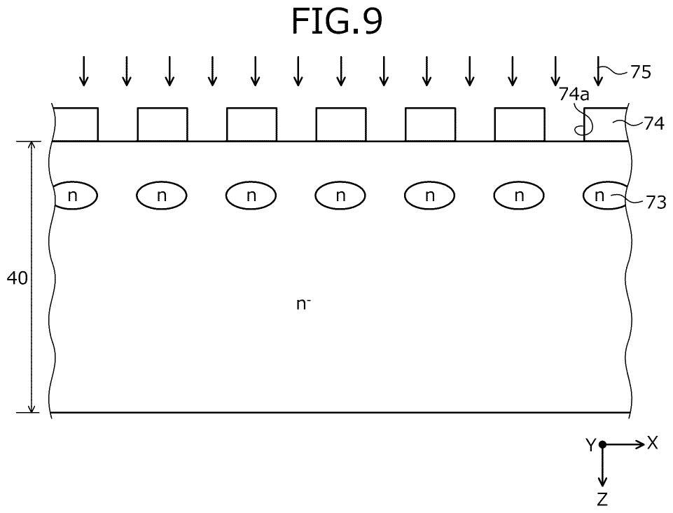

A semiconductor device according to a second embodiment solving the problems described above is described. FIG. 7 is a cross-sectional view depicting a structure of the semiconductor device according to the second embodiment. FIGS. 8 and 9 are cross-sectional views depicting examples of a state of the semiconductor device according to the second embodiment during manufacture. A layout of the semiconductor device 60 according to the second embodiment when viewed from the front surface of the semiconductor substrate 40 is a same as any one of the layouts depicted, respectively, in FIGS. 1 and 2 in which reference numeral 30 is replaced with reference numeral 60. In the semiconductor device 60 according to the second embodiment, cross-sections along cutting line A1-A2 and cutting line A1-A2-A3 in FIG. 1 are, respectively, a same as the cross-sections depicted, respectively, in FIGS. 3 and 5 while an example of a layout of the sensing region 34 in FIGS. 3 and 5 is a same as the layout depicted in FIG. 6. In FIG. 7, bottoms of the trenches 26 of the current sensing portion 20 are indicated by a dotted line.

The semiconductor device 60 according to the second embodiment differs from the semiconductor device 30 according to the first embodiment (refer to FIGS. 1 to 6) in that an average carrier concentration per unit volume of each of multiple CS regions (second storage regions) 61 of the sensing region 34 is lower than an average carrier concentration per unit volume of the CS regions 3 in the active-region operating region 32 (FIG. 7). In particular, each of the CS regions 61 of the cells 29 of the sensing region 34 has a configuration in which a first portion 61a of a relatively high carrier concentration and a second portion 61b of a relatively low carrier concentration are disposed adjacent to one another repeatedly alternating in the longitudinal direction (the first direction X) of the trenches 26.

A maximum carrier concentration of the first portions 61a of each of the CS regions 61 is substantially a same as the maximum carrier concentration of the CS regions 3 of the active-region operating region 32. A thickness d1 of the first portions 61a of each of the CS regions 61, for example, is substantially a same as a thickness of each of the CS regions 3 of the active-region operating region 32. A carrier concentration of the second portions 61b of each of the CS regions 61 is lower than a carrier concentration of the first portions 61a of each of the CS regions 61. The carrier concentration of the second portions 61b of each of the CS regions 61 may be made lower than the carrier concentration of the first portions 61a of each of the CS regions 61 by making a thickness d2 of the second portions 61b of each of the CS regions 61 thinner than the thickness d1 of the first portions 61a of each of the CS regions 61.

In an instance in which the thickness of each of the CS regions 61 is relatively thinner in the second portions 61b, a lower surface (surface facing the n⁺-type collector region 13) of each of the CS regions 61 is recessed toward the p-type base regions 22 in the second portions 61b, thereby forming a wavy shape. In other words, a lower portion (portion facing the n⁺-type collector region 13) of each of the CS regions 61 is partially thinned. As described, in each of the CS regions 61, the second portions 61b are disposed thereby reducing the carrier concentration in portions, whereby in each of the CS regions 61, the average carrier concentration per unit volume may be made lower than the average carrier concentration per unit volume of each of the CS regions 3 in the active-region operating region 32.

The first and second portions 61a, 61b of the CS regions 61 may be formed concurrently by a single session of an ion implantation 72 (performing an ion implantation process one time) by suitably setting a pattern of openings of an ion implantation mask 71 (FIG. 8). For example, the ion implantation 72 of an n-type dopant is performed to the semiconductor substrate 40, using the ion implantation mask 71, which has openings at portions corresponding to formation regions (not depicted) of the CS regions 3 of the active-region operating region 32 and formation regions 73 of the first portions 61a of each of the CS regions 61. The CS regions 3 and the first portions 61a of each of the CS regions 61 are formed concurrently and thus, the thickness d1 of the first portions 61a of each of the CS regions 61 and the thickness of each of the CS regions 3 of the active-region operating region 32 are substantially a same.

By a heat treatment (dopant diffusion) thereafter, the dopant implanted in the first portions 61a of the CS regions 61 is diffused, whereby the first portions 61a scattered in the first direction X become connected to one another. Portions connecting adjacent ones of the first portions 61a in the first direction X constitute the second portions 61b of the CS regions 61. The ion implantation 72 of the n-type dopant is not performed in the formation regions of the second portions 61b of the CS regions 61 (FIG. 8). Therefore, the carrier concentration of the second portions 61b of each of the CS regions 61 is lower than the carrier concentration of the first portions 61a of each of the CS regions 61. Before the heat treatment process for diffusing the dopant, a separate ion implantation 75 for forming the second portions 61b of the CS regions 61 may be performed with a dose amount that is lower than a dose amount of the ion implantation 72 for forming the first portions 61a of each of the CS regions 61 (FIG. 9).

The ion implantation mask 71 suffices to have an opening pattern covering the formation regions of the second portions 61b of the CS regions 61 of the sensing region 34. In particular, in the ion implantation mask 71 in the active-region operating region 32, openings (not depicted) are formed in a striped opening pattern extending in the first direction X, so as to expose an entire surface of the formation regions of the CS regions 3. In the ion implantation mask 71 in the sensing region 34, for example, openings 71a are formed in a striped opening pattern extending in the second direction Y over an entire area of the sensing region 34 so that, for example, only the formation regions 73 of the first portions 61a of the CS regions 61 are exposed.

In the sensing region 34, the ion implantation 72 is performed at least in the formation regions 73 of the first portions 61a of each of the CS regions 61. Thus, a maximum carrier concentration of the first portions 61a of the CS regions 61 is substantially a same as the maximum carrier concentration of the CS regions 3 of the active-region operating region 32. In an instance in which the ion implantation 72 is performed in a direction orthogonal to the front surface of the semiconductor substrate 40 (FIG. 8), in the formation regions of the second portions 61b of the CS regions 61, the n-type dopant is not implanted by the ion implantation 72. The second portions 61b of the CS regions 61 are formed by thermal diffusion of the n-type dopant from the first portions 61a of the CS regions 61 and thus, have a maximum carrier concentration that is lower than the maximum carrier concentration of the first portions 61a of the CS regions 61.

In an instance in which the ion implantations 72, 75 are performed multiple times to the front surface of the semiconductor substrate 40 to form the CS regions 61 (FIGS. 8 and 9), the maximum carrier concentration of the first portions 61a and the maximum carrier concentration of the second portions 61b of the CS regions 61 may be controlled by the dose amounts of the ion implantations 72, 75 performed multiple times. In this instance, the maximum carrier concentration of the second portions 61b of the CS regions 61 may be lower than the maximum carrier concentration of the maximum carrier concentration of the first portions 61a of the CS regions 61, and an implantation depth of the ion implantation 75 for forming the second portions 61b of the CS regions 61 may be deeper than or shallower than the formation regions 73 of the first portions 61a of each of the CS regions 61 (implantation depth of the ion implantation 72).

An ion implantation mask 74 used in the ion implantation 75 for forming the second portions 61b of the CS regions 61 suffices to have an opening pattern covering the formation regions 73 of the first portions 61a of the CS regions 61. Thus, in the ion implantation mask 74, for example, openings 74a are formed in an opening pattern extending in a striped pattern in the second direction Y over an entire area of the sensing region 34 so that, for example, only the formation regions of the second portions 61b of the CS regions 61 are exposed (FIG. 9). Further, in the ion implantation 75 for forming the second portions 61b of the CS regions 61, oblique ion implantation may be performed from a direction oblique to the front surface of the semiconductor substrate 40.

The second portions 61b may be disposed at a constant period in the CS regions 61. As a result, imbalances of breakdown voltage at the surface of the sensing region 34 may be suppressed. Further, the second portions 61b are disposed in each of the CS regions 61, whereby the average carrier concentration of the CS regions 61 per unit area decreases and thus, the CS regions 61 may be disposed in all the cells 29 of the current sensing portion 20. Further, the first and second portions 61a, 61b of the CS regions 61 may be disposed so as to be adjacent to and repeatedly alternate one another in the second direction Y (lateral direction of the trenches 26), in a striped pattern extending in the first direction X (longitudinal direction of the trenches 26).

As described above, according to the second embodiment, even in an instance in which the average carrier concentration of the CS regions per unit area of the sensing region is lowered in portions, effects similar to effects of the first embodiment may be obtained.

In the foregoing, the present disclosure is not limited to the described embodiments and various modifications within a range not departing from the spirit of the disclosure are possible. For example, in the embodiments described above, the carrier concentration of the CS regions (or the first portions of the CS regions) of the current sensing portion across the entire area thereof, may be lower than the carrier concentration of the CS regions of the main semiconductor device. In this instance, the CS regions may be disposed in all the cells of the current sensing portion. To make the carrier concentration of the CS regions of the current sensing portion lower than the carrier concentration of the CS regions of the main semiconductor device, the CS regions of the current sensing portion suffice to formed at a timing different from the timing of the formation of the CS regions of the main semiconductor device.

Further, monitoring of voltage changes at the sensing resistor and detection of overcurrent of the main semiconductor device may be performed by a high function portion disposed on the semiconductor substrate of the main semiconductor device. Further, the present disclosure is not limited to an IGBT and is further applicable to a metal oxide semiconductor field effect transistor (MOSFET) having an insulated gate with a three-layered metal-oxide-semiconductor structure. Further, in the embodiments, while a first conductivity type is assumed to be an n-type and a second conductivity type is assumed to be p-type, the present invention is similarly implemented when the first conductivity type is a p-type and the second conductivity type is an n-type.

According to the disclosure above, on-characteristics of the second device may be lower than the on-characteristics of the first device. Thus, in an instance in which the second device is used as a current sensing portion for detecting overcurrent flowing through the first device, when the first and second devices turn on, conductivity modulation in the second device is delayed relative to the first device and the rising edge of the sensing current flowing through the second device is delayed. As a result, increases in the sensing voltage (difference in potential occurring between the ends of the sensing resistor due to the flow of the sensing current) may be suppressed to a certain extent and thus, erroneous operation of a protective function of the first device during normal turn-on may be suppressed.

The semiconductor device according to the present disclosure achieves an effect in that protective capability against overcurrent may be enhanced.

As described, the semiconductor device according to the present disclosure is useful for power semiconductor devices used in power converting equipment, power source devices of various types of industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate having a first main surface and a second main surface opposite to each other;
a first device region of the semiconductor substrate;
a second device region of the semiconductor substrate outside the first device region;
a first device provided in the first device region;
a second device provided in the second device region;
a first semiconductor region of a first conductivity type, provided in the semiconductor substrate, the first semiconductor region being common to the first device and the second device;
a second semiconductor region of a second conductivity type, provided between the second main surface of the semiconductor substrate and the first semiconductor region, the second semiconductor region being common to the first device and the second device; and
a back electrode provided at the second main surface of the semiconductor substrate and electrically connected to the second semiconductor region,
wherein the first device includes:
a third semiconductor region of the second conductivity type, provided in the first device region, between the first main surface of the semiconductor substrate and the first semiconductor region;
a plurality of fourth semiconductor regions of the first conductivity type, selectively provided between the first main surface of the semiconductor substrate and the third semiconductor region;
a first storage region of the first conductivity type, provided between the third semiconductor region and the first semiconductor region, the first storage region having a doping concentration higher than a doping concentration of the first semiconductor region;
a plurality of first trenches penetrating through the plurality of fourth semiconductor regions and the third semiconductor region from the first main surface of the semiconductor substrate and terminating in the first semiconductor region;
a plurality of first gate insulating films respectively provided in the plurality of trenches;
a plurality of first gate electrodes respectively provided in the plurality of first trenches, on the plurality of first gate insulating films respectively therein; and
a first electrode provided at the first main surface of the semiconductor substrate and electrically connected to the third semiconductor region and the plurality of fourth semiconductor regions, wherein the second device includes:
a fifth semiconductor region of the second conductivity type, provided in the second device region, between the first main surface of the semiconductor substrate and the first semiconductor region;
a plurality of sixth semiconductor regions of the first conductivity type, selectively provided between the first main surface of the semiconductor substrate and the fifth semiconductor region;
a second storage region of the first conductivity type, provided between the fifth semiconductor region and the first semiconductor region, the second storage region having a doping concentration higher than the doping concentration of the first semiconductor region;
a plurality of second trenches penetrating through the plurality of sixth semiconductor regions and the fifth semiconductor region from the first main surface of the semiconductor substrate and terminating in the first semiconductor region;
a plurality of second gate insulating films respectively provided in the plurality of second trenches;
a plurality of second gate electrodes provided in the plurality of second trenches, on the second gate insulating films respectively therein; and
a second electrode provided at the first main surface of the semiconductor substrate and electrically connected to the fifth semiconductor region and the plurality of sixth semiconductor regions, and
wherein an average carrier concentration of the second storage region per unit area of the second device region is lower than an average carrier concentration of the first storage region per unit area of the first device region.

2. The semiconductor device according to claim 1, wherein the average carrier concentration of the second storage region per unit area of the second device region is 0.2 times to 0.6 times the average carrier concentration of the first storage region per unit area of the first device region.

3. The semiconductor device according to claim 1, wherein the second storage region has a plurality of first portions and a plurality of second portions having a carrier concentration lower than a carrier concentration of the plurality of first portions.

4. The semiconductor device according to claim 3, wherein a thickness of each of the plurality of second portions is thinner than a thickness of each of the plurality of first portions.

5. The semiconductor device according to claim 4, wherein the second storage region has a lower surface facing the back electrode, the lower surface having a plurality of recesses respectively recessed toward the second electrode, at respective ones of the plurality of second portions, thereby forming a wavy shape.

6. The semiconductor device according to claim 3, wherein a carrier concentration of the plurality of first portions is a same as a carrier concentration of the first storage region.

7. The semiconductor device according to claim 1, wherein a carrier concentration of the second storage region is lower than a carrier concentration of the first storage region over an entire area of the second storage region.

8. The semiconductor device according to claim 1, wherein
the first device has a plurality of first cells each having the third semiconductor region, the plurality of fourth semiconductor regions, the first storage region, and the plurality of first gate electrodes,
the second device has a plurality of second cells fewer in number than a number of first cells included in the plurality of first cells of the first device,
the plurality of second cells includes:
a plurality of third cells each having the fifth semiconductor region, the plurality of sixth semiconductor regions, the second storage region, and the plurality of second gate electrodes, and
a plurality of fourth cells each having the fifth semiconductor region, the plurality of sixth semiconductor regions, and the plurality of second gate electrodes, the plurality of fourth cells being free of the second storage region.

9. The semiconductor device according to claim 8, wherein the plurality of third cells and the plurality of fourth cells are disposed repeatedly at a constant period.
